(19) United States
(12) Patent Application Publication
(10) Pub. No.: US 2025/0228111 A1
(43) Pub. Date: Jul. 10, 2025

(54) DISPLAY PANEL AND DISPLAY DEVICE

(71) Applicant: Wuhan China Star Optoelectronics Semiconductor Display Technology Co., Ltd., Wuhan, Hubei (CN)

(72) Inventor: Jing NI, Wuhan, Hubei (CN)

(73) Assignee: Wuhan China Star Optoelectronics Semiconductor Display Technology Co., Ltd., Wuhan, Hubei (CN)

(21) Appl. No.: 18/852,532

(22) PCT Filed: Jun. 28, 2023
(86) PCT No.: PCT/CN2023/103071

§ 371 Date: Sep. 30, 2024

(30) Foreign Application Priority Data
Nov. 29, 2022 (CN) 202211518080.0

(51) Int. Cl. H10K 59/80; H01L 25/075; H10H 29/24; H10H 29/85; H10H 29/855; H10K 59/126; H10K 59/38; H10K 59/40

(52) U.S. Cl. CPC H10K 59/879; H10H 29/24; H10H 29/8517; H10H 29/855; H10K 59/126; H10K 59/38; H10K 59/40; H01L 25/0753

(57) ABSTRACT

A display panel and a display device are disclosed. The display panel includes an underlay substrate, a light emitting functional layer, a light shielding layer, a light extraction layer, and a light filter layer. The light emitting functional layer includes a plurality of light emitting units. The light shielding layer includes a plurality of first apertures. The first apertures are disposed to correspond to the light emitting units. The light extraction layer covers sidewalls of the first apertures and comprises a plurality of second apertures. The light filter layer includes a plurality of light filter units. The light filter units are filled in the second apertures, and a refractive index of the light extraction layer is less than a refractive index of the light filter unit.

### FIELD OF INVENTION

The present application relates to a field of display technologies, especially to a display panel and a display device.

### BACKGROUND OF INVENTION

Organic light-emitting diode (OLED) display panels, compared to liquid crystal displays, offer advantages such as thinner profiles, superior display effects, higher resolution, wider color gamut, lower power consumption, and the ability to achieve flexible displays. These advantages have fueled the rapid development of OLEDs in recent years, making them the preferred display panel type for mobile terminals.

To further reduce the production cost of OLED display panels and make them even thinner, a new architecture employing a black matrix (BM) and color filter (CF) has been proposed to replace the conventional polarizer with anti-reflection properties. However, this architecture suffers from low light-emitting efficiency, leading to higher power consumption in OLED display panels, which is a problem that needs to be urgently addressed.

### SUMMARY OF INVENTION

The present application provides a display panel and a display device able to effectively solve the issue of the low light emitting efficiency and high power consumption existing in the conventional display panel and display device.

In an aspect, the present application provides a display panel, and the display panel comprises: an underlay substrate; a light emitting functional layer disposed on a side of the underlay substrate and comprising a plurality of light emitting units; a light shielding layer disposed on a side of the light emitting functional layer away from the underlay substrate and comprising a plurality of first apertures, wherein the first apertures are disposed to correspond to the light emitting units; a light extraction layer at least covering sidewalls of the first apertures and comprising a plurality of second apertures, wherein the second apertures are disposed to correspond to the light emitting units; and a light filter layer comprising a plurality of light filter units, wherein the light filter units are filled in the second apertures respectively and are disposed to correspond to the light emitting units; wherein a refractive index of the light extraction layer is less than a refractive index of the light filter units.

Optionally, the display panel further comprises: inorganic layer disposed on the side of the light emitting functional layer away from the underlay substrate and contacts a surface of a side of the light shielding layer facing the underlay substrate; wherein the light extraction layer extends through the first apertures and contacts the inorganic layer, and the light extraction layer comprises: an inorganic contact part contacting the inorganic layer, wherein the inorganic contact part is inorganic material.

Optionally, the display panel further comprises: a touch function layer disposed on the side of the light emitting functional layer away from the underlay substrate and comprising a touch electrode layer and an inorganic layer; wherein the touch electrode layer comprises a touch electrode disposed to correspond to the light shielding layer, and the light extraction layer is inorganic material; and wherein the inorganic layer is disposed on a side of the touch electrode layer away from the underlay substrate.

Optionally, an edge of an end of the first aperture near the inorganic layer is a first edge, an edge of an end of the second aperture near the inorganic layer is a second edge, wherein a distance between the first edge and the second edge is greater than or equal to 1 μm.

Optionally, along a direction from the underlay substrate toward the light extraction layer, areas of the second apertures gradually increase, an included angle between a sidewall of the second aperture and the underlay substrate is k, and 45<k<90°.

Optionally, a depth of the second aperture is b, a distance between the first edge and the second edge is less than b/tan (2k−90°).

Optionally, a depth of the first aperture is a, and a thickness of the light filter units is c, wherein 0<a<b<c.

Optionally, the light emitting units comprise: red light emitting units, green light emitting units, and blue light emitting units; the light filter units comprise: red light filter units, green light filter units, and blue light filter units, the red light filter units are disposed to correspond to the red light emitting units, the green light filter units are disposed to correspond to the green light emitting units, and the blue light filter units are disposed to correspond to the blue light emitting units;
wherein a refractive index of the red light filter units is z1; a refractive index of the green light filter units is z2; and a refractive index of the blue light filter units is z3; and 0<z3<z1<z2; wherein the light extraction layer comprises: first light extraction units, second light extraction units, and third light extraction units, the first light extraction units are disposed to correspond to the red light filter units, the second light extraction units are disposed to correspond to the green light filter units, and the third light extraction units are disposed to correspond to the blue light filter units; and wherein an included angle between a sidewall of the second aperture in the first light extraction unit and the underlay substrate is k1, an included angle between a sidewall of the second apertures in the second light extraction unit and the underlay substrate is k2, and an included angle between a sidewall of the second aperture in the third light extraction unit and the underlay substrate is k3; wherein k2<k1<k3.

Optionally, each of the first light extraction units, the second light extraction units, and the third light extraction units comprises one of the second apertures, a depth of the second aperture in the first light extraction unit is b1; a depth of the second aperture in the second light extraction unit is b2; a depth of the second aperture in the third light extraction unit is b3; and 0<b2<b1<b3.

Optionally, the light extraction layer further comprises: a first extension portion at least partially covering a side of the light shielding layer away from the underlay substrate; the light filter layer further comprises: a second extension portion at least covering the side of the light shielding layer away from the underlay substrate; and the second extension portion and the light shielding layer are spaced from the first extension portion, or, the second extension portion covers the first extension portion and directly contacts the side of the light shielding layer away from the underlay substrate surface.

In another aspect, the present application also provides a display device, the display device comprises a casing and any one of the above display panels, wherein an accommodation space is formed in the casing, and the display panel is disposed in the accommodation space.

### Beneficial Effect

The present application provides a display panel and a display device, and the display panel comprises: an underlay substrate, a light emitting functional layer, a light shielding layer, a light extraction layer, and a light filter layer. The light emitting functional layer comprises a plurality of light emitting units. The light filter layer comprises a plurality of light filter units. The present application improves the light emitting efficiency and display quality of a display panel by filling the light filter units, which correspond to the light emitting units, into the second apertures of the light extraction layer. By setting the refractive index of the light extraction layer to be less than that of the light filter units, a portion of the emerging light emitted from the light emitting units is able to be directed onto the sidewalls of the second apertures via the light filter units. Subsequently, after undergoing total reflection on the sidewalls of the second apertures, this portion of the emerging light is emitted from the light exiting side of the display panel. As a result, the absorption of this portion of the emerging light by the light shielding layer is reduced or avoided, thereby enhancing the light emitting efficiency and display quality of the display panel.

### DESCRIPTION OF DRAWINGS

To more clearly elaborate on the technical solutions of embodiments of the present invention or prior art, appended figures necessary for describing the embodiments of the present invention or prior art will be briefly introduced as follows. Apparently, the following appended figures are merely some embodiments of the present invention. A person of ordinary skill in the art may also acquire other figures according to the appended figures without any creative effort.

FIG. 1 is a schematic structural view of the display panel provided by a first embodiment of the present application.

FIG. 2 is a schematic structural view of the display panel provided by a second embodiment of the present application.

FIG. 3 is a schematic structural view of the display panel provided by a third embodiment of the present application.

FIG. 4 is a schematic structural view of the display panel provided by a fourth embodiment of the present application.

### DETAILED DESCRIPTION OF PREFERRED EMBODIMENTS

The technical solution in the embodiment of the present application will be clearly and completely described below with reference to the accompanying drawings in the embodiments of the present application. Apparently, the described embodiments are merely some embodiments of the present application instead of all embodiments. According to the embodiments in the present application, all other embodiments obtained by those skilled in the art without making any creative effort shall fall within the protection scope of the present application. In addition, it should be understood that the specific embodiments described here are only used to illustrate and explain the present application, and are not used to limit the present application. In the present application, the used orientation terminologies such as “upper” and “lower”, when not specified to the contrary explanation, usually refer to the upper and lower states of the device in actual use or working conditions, specifically according to the direction of the figures in the drawings. Furthermore, “inner” and “outer” refer to the outline of the device.

The following disclosure provides many different embodiments or examples to achieve different structures of the present application. To simplify the disclosure of the present application, the components and arrangements of the specific examples are described below. Of course, they are merely examples, and the purpose is not to limit the present application. Furthermore, the present application may repeat reference numerals and/or reference letters in different examples. The repetition is for the purpose of simplification and clarity, and does not by itself indicate the relationship between the various embodiments and/or settings discussed. In addition, the present application provides examples of various specific processes and materials, but a person of ordinary skill in the art can be aware of the application of other processes and/or the use of other materials. It should be explained that the order of descriptions in the following embodiments is not to limit the preferred order of the embodiments.

### Embodiment 1

FIG. 1 is a schematic structural view of the display panel provided by a first embodiment of the present application. With reference to FIG. 1, the embodiment 1 of the present application provides a display panel, and the display panel comprises: an underlay substrate 10, a light emitting functional layer 20, a light shielding layer 50, a light extraction layer 60, and a light filter layer 70. The light emitting functional layer 20 is disposed on a side of the underlay substrate 10 and comprises a plurality of light emitting units 21. The light shielding layer 50 is disposed on a side of the light emitting functional layer 20 away from the underlay substrate 10 and comprises a plurality of first apertures 51. The first apertures 51 are disposed to correspond to the light emitting units 21. The light extraction layer 60 at least covers sidewalls of the first apertures 51 and comprises a plurality of second apertures 61. The second apertures 61 are disposed to correspond to the light emitting units 21. The light filter layer 70 comprises a plurality of light filter units 71. The light filter units 71 are filled in the second apertures 61 and are disposed to correspond to the light emitting units 21. A refractive index of the light extraction layer 60 is less than a refractive index of the light filter unit 71.

In particular, the display panel of the present application is an organic light emitting diode (OLED) display panel or a mini/micro light emitting diode (M-LED) display panel, the display panel comprises a light exiting side, and the light exiting side is a side used by the display panel to display images.

In the display panel of the present application, because the light filter units 71 disposed to correspond to the light emitting units 21 are filled in the second apertures 61 of the light extraction layer 60 and the refractive index of the light extraction layer 60 is less than the refractive index of the light filter unit 71, some of emerging light emitted by the light emitting units 21 can irradiate the sidewalls of the second apertures 61 through the light filter units 71, undergo total reflection on the sidewalls of the second apertures 61, and exit out of the light exiting side of the display panel, thereby reducing or avoiding the part of emerging light from being absorbed by the light shielding layer 50, improving the light emitting efficiency of the display panel, and enhancing the display quality.

Furthermore, the refractive index of the light extraction layer 60 ranges from 1.4 to 1.6, and the refractive index of the light filter unit 71 ranges from 1.5 to 1.75. It should be explained that in some embodiments of the present application, the refractive index of the light extraction layer 60 can be the same or different in each region. The refractive index of each of the light filter units 71 can be the same or different.

In some embodiments of the present application, the display panel further comprises: an inorganic layer 42. The inorganic layer 42 is disposed on a side of the light emitting functional layer 20 away from the underlay substrate 10 and contacts a surface of a side of the light shielding layer 50 facing the underlay substrate 10. The light extraction layer 60 extends through the first apertures 51 and contacts the inorganic layer 42, and the light extraction layer comprises: an inorganic contact part 62 contacting the inorganic layer. The inorganic contact part 62 is an inorganic material.

In particular, in the display panel of the present application, the light shielding layer 50, for example a black matrix with an anti-mixing function, has material generally being organic material. When a surface of a side of the light shielding layer 50 facing the underlay substrate 10 contacts the inorganic layer 42 of the inorganic material, a surface of a side of the light shielding layer 50 facing the underlay substrate 10 is easily peeled off. The light extraction layer 60 of the present application, while covering the sidewalls of the first apertures 51, extends through the first apertures 51 to contact the inorganic layer 42. Also, the inorganic contact part 62 of the light extraction layer 60 contacting the inorganic layer 42 is inorganic material such that a surface adhesion between the light extraction layer 60 and the inorganic layer 42 is greater than a surface adhesion between the light shielding layer 50 and the inorganic layer 42, thereby able to ease the peeling issue of the light shielding layer 50, enhancing the stability of the display panel, and prolonging the use lifespan of the display panel.

Preferably, a part of the light extraction layer 60 contacting the light shielding layer 50 is also inorganic material, and a surface adhesion between the light extraction layer 60 and the light shielding layer 50 is greater than a surface adhesion between the light shielding layer 50 and the inorganic layer 42. A part of the light extraction layer 60 contacting the light filter unit 71 is also inorganic material, and a surface adhesion between the light extraction layer 60 and the light filter units 71 is greater than a surface adhesion between the light shielding layer 50 and the inorganic layer 42. Furthermore, the light extraction layer 60 is inorganic material. Optionally, material of each part of the light extraction layer 60 is the same, and is inorganic material.

In some embodiments of the present application, the display panel further comprises: a touch function layer 40. The touch function layer 40 is disposed on a side of the light emitting functional layer 20 away from the underlay substrate 10 and comprises a touch electrode layer 41 and an inorganic layer 42. The touch electrode layer 41 comprises a touch electrode disposed to correspond to the light shielding layer 50. The light extraction layer 60 is inorganic material. The inorganic layer 42 is disposed on a side of the touch electrode layer 41 away from the underlay substrate 10.

In particular, the touch electrode in the touch electrode layer 41 can be self-capacitive or mutual-capacitive.

Optionally, the touch electrode in the touch electrode layer 41 is mutual-capacitive and comprises a first touch electrode and a second touch electrode. The first touch electrode and the second touch electrode can be disposed in the same layer or different layers. When the first touch electrode and the second touch electrode are disposed in the same layer, the touch electrode layer 41 further comprises a touch insulation layer disposed on sides of the first touch electrode and the second touch electrode away from the underlay substrate 10, and a bridge electrode disposed on a side of the touch insulation layer away from the underlay substrate 10. The inorganic layer 42 is disposed on a side of the bridge electrode away from the underlay substrate 10. When the first touch electrode and the second touch electrode are disposed in different layers, the touch electrode layer 41 further comprises a touch insulation layer disposed on a side of the first touch electrode away from the underlay substrate 10, and a second touch electrode disposed on a side of the touch insulation layer away from the underlay substrate 10, and the inorganic layer 42 is disposed on a a side of the second touch electrode away from the underlay substrate 10.

Furthermore, material of the first touch electrode and the second touch electrode is metal, and the first touch electrode and the second touch electrode are grid-like structures. The material of the first touch electrode and the second touch electrode is metal and has certain rigidity and structures thereof are grid-like structures such that during sequential formation of the inorganic layer 42 and the light shielding layer 50 on the first touch electrode and the second touch electrode away from the underlay substrate 10, the adhesion effect between the light shielding layer 50 and the inorganic layer 42 becomes poor and easily results in the peeling issue. The present application sets the light extraction layer 60 covering the first apertures 51 and extending through the first apertures 51, thereby able to utilize the light extraction layer 60 to effectively limit and fix the light shielding layer 50, drastically reducing or removing the probability of the peeling issue between the inorganic layer 42 and the light shielding layer 50.

In some embodiments of the present application, an edge of an end of the first aperture 51 near the inorganic layer 42 is a first edge 511. An edge of an end of the second aperture 61 near the inorganic layer 42 is a second edge 611. A distance between the first edge 511 and the second edge 611 is greater than or equal to 1 μm.

In particular, in the display panel of the present application, the first edge 511, the second edge 611 and a surface of a side of the inorganic layer 42 away from the underlay substrate 10 share a surface. In the corresponding ones of the first apertures 51 and the second apertures 61, the distance between the first edge 511 and the second edge 611 is greater than or equal to 1 μm, thereby enabling a width of a contacting part of the light extraction layer 60 with the inorganic layer 42 not to be less than 1 μm, guaranteeing a contacting area between the light extraction layer 60 and the inorganic layer 42, enhancing the limiting effect of the contacting part of the light extraction layer 60 with the inorganic layer 42 to the light shielding layer 50, and further lowering the probability of the peeling issue of the light shielding layer 50.

In some embodiments of the present application, along a direction from the underlay substrate 10 toward the light extraction layer 60, areas of the second apertures 61 gradually increase, an included angle between the sidewall of the second aperture 61 and the underlay substrate 10 is k, and 45°<k<90°.

In particular, the areas of the second apertures 61 gradually increase and the included angle k between the sidewall of the second aperture 61 and the underlay substrate 10 is greater than 45° and is less than 90°, thereby able to drastically reduce or avoid the probability that some of emerging light emitted by the light emitting units 21 is reflected along a direction toward the underlay substrate 10 (namely, the backlight side of the display panel) after irradiating the sidewalls of the second apertures 61 through the light filter units 71, thereby able to further improve the light emitting efficiency of display panel and enhance the display quality. Optionally, k is 45°, 60°, 75°, or 85°.

In some embodiments of the present application, a depth of the second aperture 61 is b, and a distance between the first edge 511 and the second edge 611 is less than b/tan (2k−90°).

In particular, when the distance between the first edge 511 is the second edge 611 is greater than or equal to threshold b/tan (2k−90°), some of emerging light emitted by the light emitting units 21, after irradiating the sidewalls of the second apertures 61 through the light filter units 71, is able to undergo total reflection along a direction toward the underlay substrate 10, which results in reduction of the display panel light emitting efficiency. Therefore, the present application makes the distance between the first edge 511 is the second edge 611 less than b/tan (2k−90°), thereby able to prevent the above condition, further reducing light loss, and facilitating improvement of the light emitting efficiency of the display panel.

Furthermore, the depth of each of the second aperture 61 is the same, namely, b is a constant, the improve the manufacturing efficiency for the patterned light extraction layer 60 and lower the manufacturing cost.

In some embodiments of the present application, the depth of the first aperture 51 is a, and the thickness of the light filter units 71 is c. 0<a<b<c.

In particular, the present application sets the thickness of the light filter unit 71 greater than the depth of the second aperture 61 such that the depth of the second aperture 61 is greater than the depth of the first aperture 51 to make a length of the light filter unit 71 along an extension of the sidewall of the second aperture 61 greater than a length of the sidewall of the second aperture 61 and make the length of the sidewall of the second aperture 61 greater than the length of the sidewall of the first aperture 51, which facilitates the emerging light emitted from the light emitting units 21 to emit out from the light exiting side of the display panel with a higher light emitting efficiency to further improve the display quality of the display panel.

In some embodiments of the present application, the light emitting units 21 comprise: red light emitting units 211, green light emitting units 212, and blue light emitting units 213. The light filter units 71 comprise: red light filter units 711, green light filter units 712, and blue light filter units 713. The red light filter units 711 are disposed to correspond to the red light emitting units 211. The green light filter units 712 are disposed to correspond to the green light emitting units 212. The blue light filter units 713 are disposed to correspond to the blue light emitting units 213. Thicknesses of the blue light filter units 713, the red light filter units 711, the green light filter units 712 are the same.

In some embodiments of the present application, the light extraction layer 60 further comprises: a first extension portion 63 at least partially covering a side of the light shielding layer 50 away from the underlay substrate 10. The light filter layer 70 further comprises: a second extension portion 72 at least covering the side of the light shielding layer 50 away from the underlay substrate 10. The second extension portion 72 and the light shielding layer 50 are spaced from the first extension portion 63.

In some embodiments of the present application, the display panel further comprises: an encapsulation layer 30, wherein the encapsulation layer 30 is configured to encapsulate and protect the light emitting units 21 in the light emitting functional layer 20 to prevent ambient water oxygen from invading an internal of the display panel and resulting in poor light emission of malfunction of the light emitting units 21. The encapsulation layer 30 is disposed on a side of the light emitting functional layer 20 away from the underlay substrate 10. The touch function layer 40 is disposed on a side of the encapsulation layer 30 away from the underlay substrate 10. The encapsulation layer 30 can be an encapsulation film layer of a single layer, or be a complex encapsulation film layer composed of the laminated inorganic encapsulation film layer and the organic encapsulation film layer.

In some embodiments of the present application, the display panel further comprises: planarization layer 80. The planarization layer 80 is disposed on a side of the light filter layer 70 away from the underlay substrate 10 to planarize sides of the light shielding layer 50, the light extraction layer 60, and the light filter layer 70 away from the underlay substrate 10.

In another aspect, the present application also provides a display device, and the display device comprises a casing and any one of the above display panels. An accommodation space is formed in the casing, and the display panel is disposed in the accommodation space.

### Embodiment 2

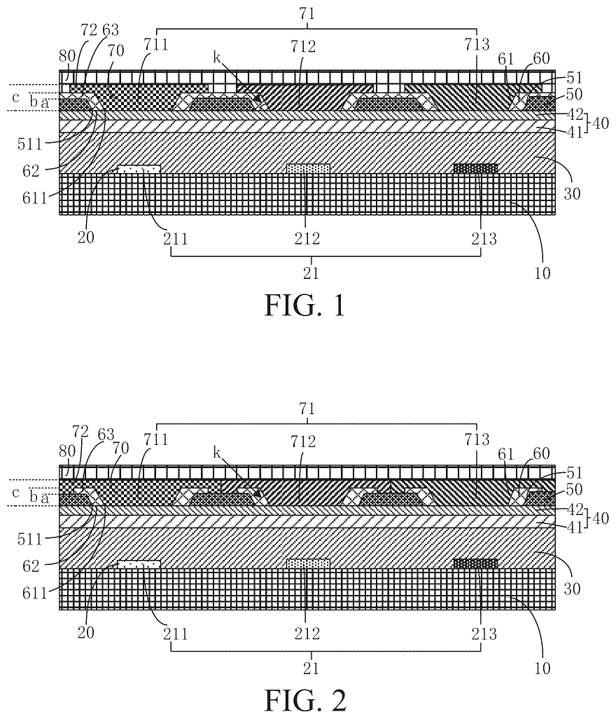

FIG. 2 is a schematic structural view of the display panel provided by a second embodiment of the present application. With reference to FIG. 1 and FIG. 2, the embodiment 2 of the present application provides a display panel, and the display panel comprises: an underlay substrate 10, a light emitting functional layer 20, a light shielding layer 50, a light extraction layer 60, and a light filter layer 70. The light emitting functional layer 20 is disposed on a side of the underlay substrate 10 and comprises a plurality of light emitting units 21. The light shielding layer 50 is disposed on a side of the light emitting functional layer 20 away from the underlay substrate 10 and comprises a plurality of first apertures 51. The first apertures 51 are disposed to correspond to the light emitting units 21. The light extraction layer 60 at least covers sidewalls of the first apertures 51 and comprises a plurality of second apertures 61. The second apertures 61 are disposed to correspond to the light emitting units 21. The light filter layer 70 comprises a plurality of light filter units 71. The light filter units 71 are filled in the second apertures 61 and are disposed to correspond to the light emitting units 21. A refractive index of the light extraction layer 60 is less than a refractive index of the light filter unit 71.

It should be explained that the display panel provided by the embodiment 2 of the present application is structurally similar to the display panel in the embodiment 1 of the present application, and the present embodiment does not repeatedly describe the same parts.

In the display panel of the present embodiment, the light extraction layer 60 further comprises: a first extension portion 63 at least partially covering the side of the light shielding layer 50 away from the underlay substrate 10. The light filter layer 70 further comprises: a second extension portion 72 at least partially covering the side of the light shielding layer 50 away from the underlay substrate 10. The second extension portion 72 covers the first extension portion 63 and directly contacts the side of the light shielding layer 50 away from the underlay substrate 10 surface.

In another aspect, the present application also provides a display device, and the display device comprises a casing and any one of the above display panels. An accommodation space is formed in the casing, and the display panel is disposed in the accommodation space.

### Embodiment 3

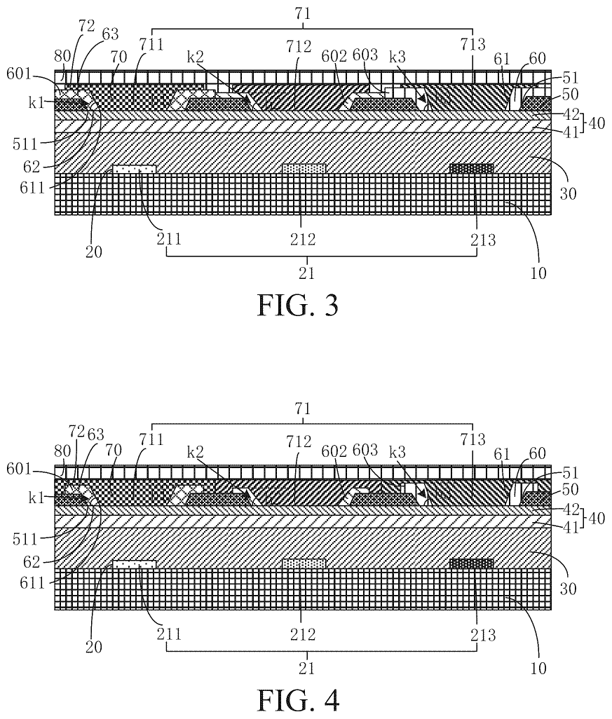

FIG. 3 is a schematic structural view of the display panel provided by a third embodiment of the present application. With reference to FIG. 1 and FIG. 3, the embodiment 3 of the present application provides a display panel, and the display panel comprises: an underlay substrate 10, a light emitting functional layer 20, a light shielding layer 50, a light extraction layer 60, and a light filter layer 70. The light emitting functional layer 20 is disposed on a side of the underlay substrate 10 and comprises a plurality of light emitting units 21. The light shielding layer 50 is disposed on a side of the light emitting functional layer 20 away from the underlay substrate 10 and comprises a plurality of first apertures 51. The first apertures 51 are disposed to correspond to the light emitting units 21. The light extraction layer 60 at least covers sidewalls of the first apertures 51 and comprises a plurality of second apertures 61. The second apertures 61 are disposed to correspond to the light emitting units 21. The light filter layer 70 comprises a plurality of light filter units 71. The light filter units 71 are filled in the second apertures 61 and are disposed to correspond to the light emitting units 21. A refractive index of the light extraction layer 60 is less than a refractive index of the light filter unit 71.

It should be explained that the display panel provided by the embodiment 3 of the present application is structurally similar to in the display panel of the embodiment 1 of the present application, for example, the light emitting units 21 comprise: red light emitting units 211, green light emitting units 212, and blue light emitting units 213. The light filter units 71 comprise: red light filter units 711, green light filter units 712, and blue light filter units 713. The red light filter units 711 are disposed to correspond to the red light emitting units 211. The green light filter units 712 are disposed to correspond to the green light emitting units 212. The blue light filter units 713 are disposed to correspond to the blue light emitting units 213. The present embodiment does not repeatedly describe the same parts.

In the display panel of the present embodiment, a refractive index of the red light filter unit 711 is z1. A refractive index of the green light filter unit 712 is z2. A refractive index of the blue light filter units 713 is z3. 0<z3<z1<z2. The light extraction layer 60 comprises: first light extraction units 601, second light extraction units 602, and third light extraction units 603. The first light extraction units 601 are disposed to correspond to the red light filter units 711. The second light extraction units 602 are disposed to correspond to the green light filter units 712. The third light extraction units 603 are disposed to correspond to the blue light filter units 713. An included angle between the sidewall of the second aperture 61 in the first light extraction unit 601 and the underlay substrate 10 is k1. An included angle between the sidewall of the second aperture 61 of the second light extraction unit 602 and the underlay substrate 10 is k2. An included angle between the sidewall of the second aperture 61 of the third light extraction unit 603 and the underlay substrate 10 is k3. k2<k1<k3.

In particular, to improve the light emission brightness of the display panel at the direct angle, non-vertically emitted emerging light emitted from the light emitting units 21 is required, after reflected by the sidewalls of second apertures 61 in the light extraction layer 60, to be along a direction perpendicular to the underlay substrate 10 as much as possible. Then, the included angle k between the sidewall of the second aperture 61 and the underlay substrate 10 fulfills the following equation: k=arcsin (the refractive index of the light extraction layer)/(the refractive index of the light filter unit).)

Accordingly, the refractive indexes of the first light extraction units 601, the second light extraction units 602, and the third light extraction units 603 are set equal. The greater the refractive index of the light filter units 71 is, the less the k is. Because the refractive index of the blue light filter unit 713 is less than the refractive index of the red light filter unit 711, the refractive index of the red light filter unit 711 is less than the refractive index of the green light filter unit 712. Therefore, k2<k1<k3. Namely, when k2<k1<k3, the brightness of the display panel at the direct angle can be increased drastically, thereby further improving the display quality of the display panel.

In some embodiments of the present application, each of the first light extraction units 601, the second light extraction units 602, and the third light extraction units 603 comprises one of the second apertures 61. A depth of the second aperture 61 in the first light extraction unit 601 is b1. A depth of the second aperture 61 in the second light extraction unit 602 is b2. A depth of the second aperture 61 in the third light extraction units 603 is b3, and 0<b2<b1<b3.

In particular, the blue light emitting units 213 light effect improvement efficiency is greater than red light emitting units 211 light effect improvement efficiency. the red light emitting units 211 light effect improvement efficiency is greater than green light emitting units 212 light effect improvement efficiency. The present application, by configuring the depth of the second aperture 61 in the third light extraction unit 603 to be greater than the depth of the second aperture 61 in the first light extraction unit 601, and configuring the depth of the second aperture 61 in the first light extraction unit 601 to be greater than the depth of the second aperture 61 in the second light extraction unit 602, can further enhance the light effect improvement efficiency of the light extraction layer to the display panel while guaranteeing the display quality of the display panel.

In another aspect, the present application also provides a display device, the display device comprises a casing and any one of the above display panels. An accommodation space is formed in the casing, and the display panel is disposed in the accommodation space.

### Embodiment 4

FIG. 4 is a schematic structural view of the display panel provided by a fourth embodiment of the present application. With reference to FIG. 3 and FIG. 4, the embodiment 4 of the present application provides a display panel, and the display panel comprises: an underlay substrate 10, a light emitting functional layer 20, a light shielding layer 50, a light extraction layer 60, and a light filter layer 70. The light emitting functional layer 20 is disposed on a side of the underlay substrate 10 and comprises a plurality of light emitting units 21. The light shielding layer 50 is disposed on a side of the light emitting functional layer 20 away from the underlay substrate 10 and comprises a plurality of first apertures 51. The first apertures 51 are disposed to correspond to the light emitting units 21. The light extraction layer 60 at least covers sidewalls of the first apertures 51 and comprises a plurality of second apertures 61. The second apertures 61 are disposed to correspond to the light emitting units 21. The light filter layer 70 comprises a plurality of light filter units 71. The light filter units 71 are filled in the second apertures 61 and are disposed to correspond to the light emitting units 21. A refractive index of the light extraction layer 60 is less than a refractive index of the light filter unit 71.

It should be explained that the display panel provided by the embodiment 4 of the present application is structurally similar to the display panel in the embodiment 3 of the present application, and the present embodiment does not repeatedly describe the same parts.

In the display panel of the present embodiment, in the display panel of the present embodiment, the light extraction layer 60 further comprises: a first extension portion 63 at least partially covering the side of the light shielding layer 50 away from the underlay substrate 10. The light filter layer 70 further comprises: a second extension portion 72 at least partially covering the side of the light shielding layer 50 away from the underlay substrate 10. The second extension portion 72 covers the first extension portion 63 and directly contacts the side of the light shielding layer 50 away from the underlay substrate 10 surface.

In another aspect, the present application also provides a display device, the display device comprises a casing and any one of the above display panels, an accommodation space is formed in the casing, and the display panel is disposed in the accommodation space.

As described above, the present application provides a display panel and a display device. The display panel comprises an underlay substrate, a light emitting functional layer, a light shielding layer, a light extraction layer, and a light filter layer. The light emitting functional layer is disposed on a side of the underlay substrate and comprises a plurality of light emitting units. The light shielding layer is disposed on a side of the light emitting functional layer away from the underlay substrate and comprises a plurality of first apertures. The first apertures are disposed to correspond to the light emitting units. The light extraction layer covers sidewalls of the first apertures and comprises a plurality of second apertures. The second apertures are disposed to correspond to the light emitting units. The light filter layer comprises a plurality of light filter units. The light filter units are filled in the second apertures and are disposed to correspond to the light emitting units. A of the light extraction layer is less than a refractive index of the light filter unit such that some of emerging light emitted by the light emitting units can irradiate the sidewalls of the second apertures through the light filter units, undergo total reflection on the sidewalls of the second aperture, and then exit out from a light exiting side of the display panel, thereby reducing or avoiding the part of emerging light from being absorbed by the light shielding layer, and improving the light emitting efficiency of the display panel.

The display panel and the display device provided by the embodiment of the present application are described in detail as above. In the specification, the specific examples are used to explain the principle and embodiment of the present application. The above description of the embodiments is only used to help understand the method of the present application and its spiritual idea. Meanwhile, for those skilled in the art, according to the present idea of invention, changes will be made in specific embodiment and application. In summary, the contents of this specification should not be construed as limiting the present application.

1. A display panel, comprising:
an underlay substrate;
a light emitting functional layer disposed on a side of the underlay substrate and comprising a plurality of light emitting units;
a light shielding layer disposed on a side of the light emitting functional layer away from the underlay substrate and comprising a plurality of first apertures, wherein the first apertures are disposed to correspond to the light emitting units;
a light extraction layer at least covering sidewalls of the first apertures and comprising a plurality of second apertures, wherein the second apertures are disposed to correspond to the light emitting units; and
a light filter layer comprising a plurality of light filter units, wherein the light filter units are filled in the second apertures respectively and are disposed to correspond to the light emitting units;
wherein a refractive index of the light extraction layer is less than a refractive index of the light filter units.

2. The display panel according to claim 1, wherein the display panel further comprises: inorganic layer disposed on the side of the light emitting functional layer away from the underlay substrate and contacts a surface of a side of the light shielding layer facing the underlay substrate; and
wherein the light extraction layer extends through the first apertures and contacts the inorganic layer, and the light extraction layer comprises: an inorganic contact part contacting the inorganic layer, wherein the inorganic contact part is inorganic material.

3. The display panel according to claim 2, wherein the display panel further comprises: a touch function layer disposed on the side of the light emitting functional layer away from the underlay substrate and comprising a touch electrode layer and an inorganic layer; wherein the touch electrode layer comprises a touch electrode disposed to correspond to the light shielding layer, and the light extraction layer is inorganic material; and
wherein the inorganic layer is disposed on a side of the touch electrode layer away from the underlay substrate.

4. The display panel according to claim 2, wherein an edge of an end of the first aperture near the inorganic layer is a first edge, an edge of an end of the second aperture near the inorganic layer is a second edge, wherein a distance between the first edge and the second edge is greater than or equal to 1 μm.

5. The display panel according to claim 4, wherein along a direction from the underlay substrate toward the light extraction layer, areas of the second apertures gradually increase, an included angle between a sidewall of the second aperture and the underlay substrate is k, and 45°<k<90°.

6. The display panel according to claim 5, wherein a depth of the second aperture is b, a distance between the first edge and the second edge is less than b/tan (2k−90°).

7. The display panel according to claim 6, wherein a depth of the first aperture is a, and a thickness of the light filter units is c, wherein 0<a<b<c.

8. The display panel according to claim 6, wherein the light emitting units comprise: red light emitting units, green light emitting units, and blue light emitting units; the light filter units comprise: red light filter units, green light filter units, and blue light filter units, the red light filter units are disposed to correspond to the red light emitting units, the green light filter units are disposed to correspond to the green light emitting units, and the blue light filter units are disposed to correspond to the blue light emitting units;
wherein a refractive index of the red light filter units is z1; a refractive index of the green light filter units is z2; and a refractive index of the blue light filter units is z3; and 0<z3<z1<z2;
wherein the light extraction layer comprises: first light extraction units, second light extraction units, and third light extraction units, the first light extraction units are disposed to correspond to the red light filter units, the second light extraction units are disposed to correspond to the green light filter units, and the third light extraction units are disposed to correspond to the blue light filter units; and
wherein an included angle between a sidewall of the second aperture in the first light extraction unit and the underlay substrate is k1, an included angle between a sidewall of the second apertures in the second light extraction unit and the underlay substrate is k2, and an included angle between a sidewall of the second aperture in the third light extraction unit and the underlay substrate is k3; wherein k2<k1<k3.

9. The display panel according to claim 8, wherein each of the first light extraction units, the second light extraction units, and the third light extraction units comprises one of the second apertures, a depth of the second aperture in the first light extraction unit is b1; a depth of the second aperture in the second light extraction unit is b2; a depth of the second aperture in the third light extraction unit is b3; and 0<b2<b1<b3.

10. The display panel according to claim 1, wherein the light extraction layer further comprises: a first extension portion at least partially covering a side of the light shielding layer away from the underlay substrate; the light filter layer further comprises: a second extension portion at least covering the side of the light shielding layer away from the underlay substrate; and
the second extension portion and the light shielding layer are spaced from the first extension portion, or, the second extension portion covers the first extension portion and directly contacts the side of the light shielding layer away from the underlay substrate surface.

11. A display device, wherein the display device comprising a casing and a display panel, wherein an accommodation space is formed in the casing, the display panel is disposed in the accommodation space, and the display panel comprises:
an underlay substrate;
a light emitting functional layer disposed on a side of the underlay substrate and comprising a plurality of light emitting units;
a light shielding layer disposed on a side of the light emitting functional layer away from the underlay substrate and comprising a plurality of first apertures, wherein the first apertures are disposed to correspond to the light emitting units;
a light extraction layer at least covering sidewalls of the first apertures and comprising a plurality of second apertures, wherein the second apertures are disposed to correspond to the light emitting units;
a light filter layer comprising a plurality of light filter units, wherein the light filter units are filled in the second apertures respectively and are disposed to correspond to the light emitting units; and
wherein a refractive index of the light extraction layer is less than a refractive index of the light filter units.

12. The display device according to claim 11, wherein the display panel further comprises: inorganic layer disposed on the side of the light emitting functional layer away from the underlay substrate and contacts a surface of a side of the light shielding layer facing the underlay substrate; and
wherein the light extraction layer extends through the first apertures and contacts the inorganic layer, and the light extraction layer comprises: an inorganic contact part contacting the inorganic layer, wherein the inorganic contact part is inorganic material.

13. The display device according to claim 12, wherein the display panel further comprises: a touch function layer disposed on the side of the light emitting functional layer away from the underlay substrate and comprising a touch electrode layer and an inorganic layer; wherein the touch electrode layer comprises a touch electrode disposed to correspond to the light shielding layer, and the light extraction layer is inorganic material; and
wherein the inorganic layer is disposed on a side of the touch electrode layer away from the underlay substrate.

14. The display device according to claim 12, wherein an edge of an end of the first aperture near the inorganic layer is a first edge, an edge of an end of the second aperture near the inorganic layer is a second edge, wherein a distance between the first edge and the second edge is greater than or equal to 1 μm.

15. The display device according to claim 14, wherein along a direction from the underlay substrate toward the light extraction layer, areas of the second apertures gradually increase, an included angle between a sidewall of the second aperture and the underlay substrate is k, and 45°<k<90°.

16. The display device according to claim 15, wherein a depth of the second aperture is b, a distance between the first edge and the second edge is less than b/tan (2k−90°).

17. The display device according to claim 16, wherein a depth of the first aperture is a, and a thickness of the light filter units is c, wherein 0<a<b<c.

18. The display device according to claim 16, wherein the light emitting units comprise: red light emitting units, green light emitting units, and blue light emitting units; the light filter units comprise: red light filter units, green light filter units, and blue light filter units, the red light filter units are disposed to correspond to the red light emitting units, the green light filter units are disposed to correspond to the green light emitting units, and the blue light filter units are disposed to correspond to the blue light emitting units;
wherein a refractive index of the red light filter units is z1; a refractive index of the green light filter units is z2; and a refractive index of the blue light filter units is z3; and 0<z3<z1<z2;
wherein the light extraction layer comprises: first light extraction units, second light extraction units, and third light extraction units, the first light extraction units are disposed to correspond to the red light filter units, the second light extraction units are disposed to correspond to the green light filter units, and the third light extraction units are disposed to correspond to the blue light filter units; and
wherein an included angle between a sidewall of the second aperture in the first light extraction unit and the underlay substrate is k1, an included angle between a sidewall of the second apertures in the second light extraction unit and the underlay substrate is k2, and an included angle between a sidewall of the second aperture in the third light extraction unit and the underlay substrate is k3; wherein k2<k1<k3.

19. The display device according to claim 18, wherein each of the first light extraction units, the second light extraction units, and the third light extraction units comprises one of the second apertures, a depth of the second aperture in the first light extraction unit is b1; a depth of the second aperture in the second light extraction unit is b2; a depth of the second aperture in the third light extraction unit is b3; and 0<b2<b1<b3.

20. The display device according to claim 11, wherein the light extraction layer further comprises: a first extension portion at least partially covering a side of the light shielding layer away from the underlay substrate; the light filter layer further comprises: a second extension portion at least covering the side of the light shielding layer away from the underlay substrate; and
the second extension portion and the light shielding layer are spaced from the first extension portion, or, the second extension portion covers the first extension portion and directly contacts the side of the light shielding layer away from the underlay substrate surface.
